(19) United States
(12) Patent Application Publication
(10) Pub. No.: US 2010/0051999 A1
(43) Pub. Date: Mar. 4, 2010

(54) LIQUID-CRYSTALLINE POLYESTER RESIN MIXTURE, AND REFLECTING PLATE AND LIGHT-EMITTING DEVICE USING THE SAME

(75) Inventors: Sadanobu IWASE, Tsuchiura-shi (JP); Shintaro Saito, Tsukuba-shi (JP); Hiroshi Harada, Tsukuba-shi (JP)

Correspondence Address: SUGHRUE MION, PLLC, 2100 PENNSYLVANIA AVENUE, N.W., SUITE 800, WASHINGTON, DC, 20037, US

(73) Assignee: SUMITOMO CHEMICAL COMPANY, LIMITED, Tokyo (JP)

(21) Appl. No.: 12/552,623

(22) Filed: Sep. 2, 2009

(30) Foreign Application Priority Data
Sep. 4, 2008 (JP) 2008-226751

(51) Int. Cl. H01L 33/00; C09K 19/04; C09K 19/06

(52) U.S. Cl. 257/98; 428/220; 252/299.6; 257/E33.067

(57) ABSTRACT

The present inventions provides a liquid-crystalline polyester resin mixture comprising a liquid-crystalline polyester, a particulate titanium oxide and at least one compound selected from the group consisting of a fatty acid amide and a fatty acid metal salt, wherein the resin mixture contains the particulate titanium oxide in an amount of 40 to 80 parts by weight and the at least one compound in an amount of 0.005 to parts by weight, both the amounts being based on 100 parts by weight of the component (A) in the resin mixture.

### BACKGROUND OF THE INVENTION

1. Technical Field

The present invention relates to a liquid-crystalline polyester resin mixture, a molded article and particularly, a reflecting plate using the liquid-crystalline polyester resin mixture and a light-emitting device using the reflecting plate.

2. Background Art

As to reflecting plates used in LED (light-emitting diode) light-emitting devices and the like, many reflecting plates made of resins are studied from the viewpoint of processability and light-weight characteristics. As such a reflecting plate made of a resin, those using a resin composition containing a filler (hereinafter sometimes referred to as a “high-reflectance filler”) and a liquid-crystalline polymer (liquid-crystalline polyester) attract remarkable attentions. For example, JP-A 2007-320996 proposes a liquid-crystalline polyester resin composition obtained by blending titanium oxide and a blue colorant in a liquid-crystalline polyester and discloses that a molded product using this resin composition has a high reflectance and a high degree of whiteness, showing that the molded product is preferable as a reflecting plate used in the vicinity of a light source.

### SUMMARY OF THE INVENTION

The reflecting plate using the resin composition disclosed in detail in JP-A 2007-320996 is obtained by blending titanium oxide in a relatively large amount in a liquid-crystalline polyester to heighten the reflectance. However, the reflecting plate obtained by blending titanium oxide in a large amount in a liquid-crystalline polyester has the problem that the reflecting plate is easily deteriorated with time and that the liquid-crystalline polyester itself is easily deteriorated in the production process of the reflecting plate.

In view of this situation, one of objects of the present invention is to provide a liquid-crystalline polyester resin mixture from which a reflecting plate having a high reflectance can be obtained even though the amount of a high-reflectance filler (titanium oxide) to be blended is smaller than that of a conventional liquid-crystalline polyester resin composition for producing a reflecting plate, and a molded article (particularly, a reflecting plate) using the resin mixture and also to provide a light-emitting using the reflecting plate.

The inventors of the present invention have made earnest studies to solve the above problems, and as a result, completed the present invention.

Namely, the present invention provides a liquid-crystalline polyester resin mixture comprising the following components (A), (B) and (C):
(A) a liquid-crystalline polyester;
(B) particulate titanium oxide; and
(C) at least one compound selected from the group consisting of a fatty acid amide and a fatty acid metal salt,
   wherein the resin mixture contains the component (B) in an amount of 40 to 80 parts by weight and the component (C) in an amount of 0.005 to 0.15 parts by weight, both the amounts being based on 100 parts by weight of the component (A) in the resin mixture.

Further, the present invention provides a molded article such as a reflecting plate obtainable by molding the resin mixture, and a light-emitting device comprising the reflecting plate obtained using the resin mixture.

According to the liquid-crystalline polyester resin mixture of the present invention, a reflecting plate which exhibits a high reflectance can be produced even though the amount of a high-reflectance filler (particulate titanium oxide) to be blended is smaller than that of a conventional liquid-crystalline polyester resin composition. This reflecting plate is expected to have a high reflectance while maintaining the superior characteristics such as heat resistance of the liquid-crystalline polyester, and therefore has a high industrial value in the production of a light-emitting device superior in the characteristics such as luminance.

### DETAILED DESCRIPTION OF THE INVENTION

The liquid-crystalline polyester resin mixture of the present invention comprises the following components (A), (B) and (C):
(A) a liquid-crystalline polyester;
(B) particulate titanium oxide; and
(C) at least one compound selected from the group consisting of a fatty acid amide and a fatty acid metal salt.
   In the liquid-crystalline polyester resin mixture of the present invention, the content of the component (B) is in the range of from 40 to 80 parts by weight and the content of the component (C) is in the range of from 0.005 to 0.15 parts by weight, both the contents being based on 100 parts by weight of the component (A) in the resin mixture.

Preferred embodiments of these components, a method of producing a liquid-crystalline polyester resin mixture containing these components, and a molded article, a reflecting plate and a light-emitting device manufactured by using this liquid-crystalline polyester resin mixture will be explained below.

### <Component (A)>

The liquid-crystalline polyester of the component (A) is a polyester which is called a thermotropic liquid-crystalline polymer and forms a melt showing optical anisotropy at 450° C. or less. Specific examples of the liquid-crystalline polyester include:

(1) liquid-crystalline polyesters obtained by combining and polymerizing an aromatic hydroxycarboxylic acid, an aromatic dicarboxylic acid and an aromatic diol;

(2) liquid-crystalline polyesters obtained by polymerizing two or more types of aromatic hydroxycarboxylic acids;

(3) liquid-crystalline polyesters obtained by combining and polymerizing an aromatic dicarboxylic acid and an aromatic diol; and

(4) liquid-crystalline polyesters obtained by reacting an aromatic hydroxycarboxylic acid with a crystalline polyester such as a polyethylene terephthalate.

In the production of the liquid-crystalline polyester, the above aromatic hydroxycarboxylic acid, aromatic dicarboxylic acid or aromatic diol may be respectively replaced with an ester forming derivative of each of these compounds. The use of the ester forming derivatives has an advantage that the liquid-crystalline polyester is produced more easily.

Here, the ester forming derivative will be briefly explained. Examples of ester forming derivatives of an aromatic hydroxycarboxylic acid or an aromatic dicarboxylic acid having a carboxyl group in its molecule include those forming acid halides or acid anhydrides by converting the carboxylic group into a highly reactive halo-formyl group or an acyloxycarbonyl group and those forming esters with alcohols or ethylene glycol in such a manner as to form a polyester by an ester exchange reaction of the carboxyl group. Also, examples of ester forming derivatives of an aromatic hydroxycarboxylic acid or an aromatic diol having a phenolic hydroxyl group in its molecule include those forming esters with lower carboxylic acids in such a manner as to form a polyester by an ester exchange reaction of the phenolic hydroxyl group.

Moreover, the above aromatic hydroxycarboxylic acid, aromatic dicarboxylic acid or aromatic diol may have a halogen atom such as a chlorine atom or a fluorine atom; an alkyl group such as a methyl group or an ethyl group; or an aryl group such as a phenyl group as a substituent on the aromatic ring to the extent that the ester forming ability is not impaired.

As the structural unit constituting the liquid-crystalline polyester, the following units may be exemplified.

Structural units derived from aromatic hydroxycarboxylic acids:

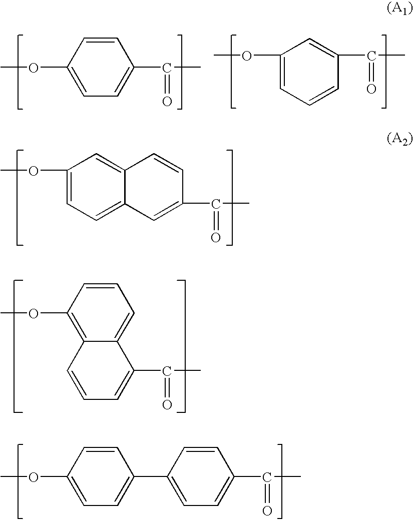

The above structural units may contain a halogen atom, an alkyl group or an aryl group as a substituent.

Structural units derived from aromatic dicarboxylic acids:

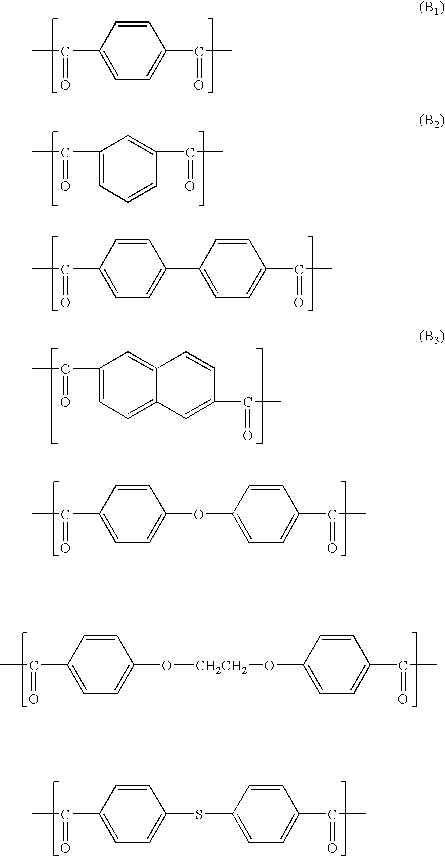

The above structural units may contain a halogen atom, an alkyl group or an aryl group as a substituent.

Structural units derived from aromatic diols:

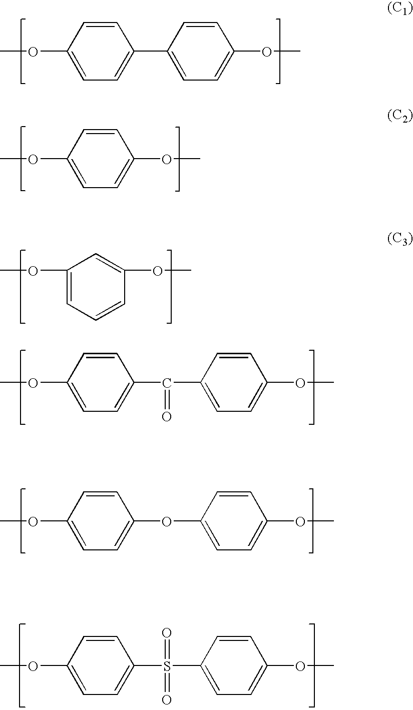

The above structural units may contain a halogen atom, an alkyl group or an aryl group as a substituent.

Preferable examples of a combination of the structural units of the liquid-crystalline polyester include the following (a) to (h):

(a): a combination of (A₁), (B₁) and (C₁) or a combination of (A₁), (B₁), (B₂) and (C₁);

(b): a combination of (A₂), (B₃) and (C₂) or a combination of (A₂), (B₁), (B₃) and (C₂);

(c): a combination of (A₁) and (A₂);

(d): a combination obtained by replacing a part or all of (A₁) in each combination of the structural units of (a) with (A₂);

(e): a combination obtained by replacing a part or all of (B₁) in each combination of the structural units of (a) with (B₃);

(f): a combination obtained by replacing a part or all of (C₁) in each combination of the structural units of (a) with (C₃);

(g): a combination obtained by replacing a part or all of (A₂) in each combination of the structural units of (b) with (A₁); and

(h): a combination obtained by adding (B₁) and (C₂) to the combination of the structural units of (c).

Preferable examples of the combination of the structural units of the liquid-crystalline polyester used as the component (A) include, similarly to the above (a) to (h), a combination of (A₁) and/or (A₂) as the structural unit derived from the aromatic hydroxycarboxylic acid, one or more types selected from the group consisting of (B₁), (B₂) and (B₃) as the structural unit derived from the aromatic diol and one or more types selected from the group consisting of (C₁), (C₂) and (C₃) as the structural unit derived from the aromatic dicarboxylic acid. Although these structural units may have a substituent on the aromatic ring, as mentioned above, they preferably have no substituent when it is demanded of the obtained molded article or reflecting plate to have higher heat resistance.

The liquid-crystalline polyester used in the component (A) has a fluidization temperature of preferably 270 to 400° C. and more preferably 300 to 380° C. If a liquid-crystalline polyester having a fluidization temperature less than 270° C. is used as the component (A), the obtained reflecting plate itself is easily deformed and easily blistered (abnormal blistering) in a high-temperature circumstance, for example, in an LED module fabrication process when it is used in a light-emitting device using LEDs as the light-emitting element. In the case of a liquid-crystalline polyester having a fluidization temperature exceeding 400° C. on the other hand, the melt processing temperature is made higher and it tends to be difficult to produce a reflecting plate, bringing about a drawback that if it is intended to process the liquid-crystalline polyester at a melt processing temperature of 400° C. or more, the liquid-crystalline polyester tends to be thermally deteriorated and, in particular cases, the reflecting plate is discolored, so that the reflectance is dropped easily. As mentioned above, a liquid-crystalline polyester having a fluidization temperature of 270 to 400° C. is particularly preferable when the liquid-crystalline polyester resin mixture of the present invention is used to produce a reflecting plate.

The fluidization temperature as used herein means the temperature at which a heat melt has a melt viscosity of 4800 Pa·sec when the heat melt is extruded from a nozzle at a temperature rise rate of 4° C./min under a load of 9.8 MPa by using a capillary type rheometer provided with a nozzle having an inside diameter of 1 mm and a length of 10 mm. This fluidization temperature is an index showing the molecular weight of a liquid-crystalline polyester well-known in the art (see “Liquid-crystalline polymer Synthesis, Molding and Application,” edited by Naoyuki Koide, pp. 95-105, CMC, published on Jun. 5, 1987).

As a method of producing the liquid-crystalline polyester, the production method which has been proposed by the applicant of the present invention in the publication of JP-A 2004-256673 is desirable though various known methods may be adopted.

The preferable method of producing a liquid-crystalline polyester which has been proposed in this publication will be explained in detail below.

A fatty acid anhydride is mixed in a mixture of an aromatic hydroxycarboxylic acid, an aromatic diol and an aromatic dicarboxylic acid and the mixture is reacted at 130 to 180° C. in a nitrogen atmosphere to acylate the phenolic hydroxyl groups of the aromatic hydroxycarboxylic acid and aromatic diol with the fatty acid anhydride, thereby obtaining an acylated product (acylated aromatic hydroxycarboxylic acid and acylated aromatic diol). Then, the mixture is heated to undergo polycondensation such that an ester exchange reaction is caused between the acyl group of the acylated product and the carboxyl groups of the acylated aromatic hydroxycarboxylic acid and aromatic dicarboxylic acid while distilling reaction byproducts out of the reaction system, to produce a liquid-crystalline polyester.

In the mixture of the aromatic hydroxycarboxylic acid, aromatic diol and aromatic dicarboxylic acid, the molar ratio of the carboxyl group to the phenolic hydroxyl group is preferably in a range from 0.9 to 1.1.

The amount of the fatty acid anhydride to be used based on the total amount of the phenolic hydroxyl groups of the aromatic diol and aromatic hydroxycarboxylic acid is preferably 0.95 to 1.2 mol times and more preferably 1.00 to 1.15 mol times.

If the amount of the fatty acid anhydride to be used is small, there is a tendency that the obtained liquid-crystalline polyester is prevented from coloring and if the amount of the fatty acid anhydride is too small, there is a fear that the unreacted aromatic diol or aromatic dicarboxylic acid is easily sublimated in the polycondensation, causing the reaction system to be clogged. When the amount of the fatty acid anhydride to be used exceeds 1.2 molar equivalents on the other hand, there is a fear that the obtained liquid-crystalline polyester is colored, which deteriorates the reflectance of the reflecting plate.

Examples of the fatty acid anhydride include, though not particularly limited to, acetic acid anhydride, propionic acid anhydride, butyric acid anhydride, isobutyric acid anhydride, valericacidanhydride, pivalicacidanhydride, 2-ethylhexanoic acid anhydride, monochloroacetic acid anhydride, dichloroacetic acid anhydride, trichloroacetic acid anhydride, monobromoacetic acid anhydride, dibromoacetic acid anhydride, tribromoacetic acid anhydride, monofluoroacetic acid anhydride, difluoroacetic acid anhydride, trifluoroacetic acid anhydride, glutaric acid anhydride, maleic acid anhydride, succinic acid anhydride and β-bromopropionicacidanhydride. These compounds maybe used in combinations of two or more. Acetic acid anhydride, propionic acid anhydride, butyric acid anhydride and isobutyric acid anhydride are preferably used and acetic acid anhydride is especially preferably used from the viewpoints of economy and handleability.

The ester exchange (polycondensation) reaction is run with raising the temperature preferably at a rate of 0.1 to 50° C./min. at a temperature range from 130 to 400° C. and more preferably at a rate of 0.3 to 5° C./min. at a temperature range from 150 to 350° C.

Then, reaction byproducts are distilled out of the system to run the ester exchange (polycondensation) reaction more smoothly.

The ester exchange (polycondensation) reaction is preferably run in the presence of a heterocyclic organic base compound having two or more nitrogen atoms from the viewpoint of producing the liquid-crystalline polyester more smoothly and of adequately limiting the coloring of the obtained liquid-crystalline polyester.

Examples of the heterocyclic organic base compound having two or more nitrogen atoms (nitrogen-containing heterocyclic organic base compound) include imidazole compounds, triazole compounds, dipyridyl compounds, phenanthroline compounds and diazaphenanthrene compounds. Among these compounds, imidazole compounds are preferably used from the viewpoint of reactivity relating to polycondensation and 1-methylimidazole and 1-ethylimidazole are more preferably used in view of easy availability.

A catalyst other than the above nitrogen-containing heterocyclic organic base compound may be used to the extent that the object of the present invention is not impaired for the purpose of promoting the ester exchange (polycondensation) reaction to increase the polycondensation reaction rate. However, when a metal salt or the like is used as the catalyst, this sometimes exerts an adverse influence on electronic parts such as a reflecting plate because the metal salt remains as impurities in the liquid-crystalline polyester. Also, in this point, the use of the above nitrogen-containing heterocyclic organic base compound is particularly preferable with the view of producing a liquid-crystalline polyester.

Examples of the method of progressing the ester exchange (polycondensation) reaction to raise the degree of polymerization of the liquid-crystalline polyester include a method (polymerization under reduced pressure) in which the pressure in the reactor used for the ester exchange reaction is dropped and a method in which the reaction product obtained after the ester exchange (polycondensation) is cooled to solidify and is then pulverized into a powder and the obtained powder is heat-treated at 250 to 350° C. for 2 to 20 hours (solid phase polymerization). By raising the degree of polymerization by such a method, it is easy to produce a liquid-crystalline polyester having a desirable fluidization temperature. It is preferable to utilize solid phase polymerization in view of the simplicity of the system.

It is preferable to undergo the above polycondensation attained by acylation and the ester exchange reaction and the polymerization under reduced pressure for the purpose of improving the degree of polymerization in an atmosphere of an inert gas such as nitrogen to sufficiently prevent the liquid-crystalline polyester from coloring.

When the liquid-crystalline polyester thus produced has a YI value of 32 or less, it is particularly preferable as the component (A). Here, the YI value of the liquid-crystalline polyester means the value obtained by measuring a test piece made of the liquid-crystalline polyester by using a color-difference meter. The YI value is an index showing the degree of yellowness, which is defined by ASTM-D1925 and can be specifically found by the following equation.

YI=[100(1.28X−1.06Z)/Y]

wherein the values of X, Y and Z are three stimulus values of light source colors in the XYZ color specification system.

The liquid-crystalline polyester which is obtained by the above production method using a nitrogen-containing heterocyclic organic base compound and has a YI value of 32 or less is particularly preferable as the component (A). However, a liquid-crystalline polyester mixture which is made to have a YI value of 32 or less by mixing plural types of liquid-crystalline polyesters may be used as the component (A). Also in this case, if the YI value of the liquid-crystalline polyester mixture is measured by the method using the aforementioned color meter, a liquid-crystalline polyester mixture preferable as the component (A) can be selected.

### <Component (B)>

The above particulate titanium oxide is a titanium compound which is primarily made of titanium oxide and has a particle shape. A material which is called “titanium oxide” in the art and is commercially available as the resin filling particle filler may be used as the component (B). In this case, a material which is called titanium oxide and is commercially available maybe used as it is and it is unnecessary to exclude unavoidable impurities. As particulate titanium oxide, one which is surface treated as will be described later may also be used.

No particular limitation is imposed on the crystal shape of titanium oxide itself to be contained and a rutile type, anatase type or a mixture of the both may be used. Particulate titanium oxide containing rutile type titanium oxide is preferable and particulate titanium oxide consisting only of rutile type titanium oxide is more preferable from the viewpoint of obtaining a reflecting plate having a higher reflectance and improving the weatherability of the reflecting plate.

Though no particular limitation is imposed on the average particle diameter (volume average particle diameter) of particulate titanium oxide, the average particle diameter is preferably 0.01 to 10 μm, more preferably 0.1 to 1 μm and even more preferably 0.1 to 0.5 μm in view of obtaining a reflecting plate having a higher reflectance and of improving the dispersibility of particulate titanium oxide in the reflecting plate. As the average particle diameter of particulate titanium oxide, titanium oxide having an optimum particle diameter may be used taking the intended thickness of the reflecting plate into account.

The average particle diameter as used herein is a volume average particle diameter found in the following manner. Specifically, the outward appearance of particulate titanium oxide is measured by a scanning electron microscope (SEM) and the obtained SEM photograph is subjected to image analysis using an image analyzer (for example, “Ruzex IIIU” manufactured by Nireco Corporation) to find a distribution curve by plotting the ratio of particles (%) in each particle size interval of primary particles. Then, the degree of accumulation of 50% (average particle diameter) is calculated from the cumulative distribution curve as the volume average particle diameter.

The amount of the component (B) to be blended in the liquid-crystalline polyester resin mixture of the present invention is 40 to 80 parts by weight and preferably 45 to 80 parts by weight based on 100 parts by weight of the component (A). When the amount of the component (B) is less than 40 parts by weight, the reflectance of the reflecting plate is insufficient, which is undesirable. When the amount of the component (B) exceeds 80 parts by weight, on the other hand, this is undesirable because there is a tendency that the production of the reflecting plate itself is difficult or the reflecting plate is easily deteriorated with time by the deterioration of the liquid-crystalline polyester. If the liquid-crystalline polyester is deteriorated, there is a disadvantage that the characteristics, such as heat resistance, of the liquid-crystalline polyester cannot be sufficiently maintained. Although the reason of the deterioration of the liquid-crystalline polyester has not been necessarily clarified, the inventors of the present invention infer that titanium oxide acts like a catalyst to cut the ester bond of the liquid-crystalline polyester to cause the liquid-crystalline polyester to be reduced in molecular weight. When the ratio of the component (B) to be blended is 80 parts by weight or less based on 100 parts by weight of the component (A), not only the deterioration of the liquid-crystalline polyester itself can be satisfactorily prevented but also the reflectance can be improved by the effect of the component (C) which will be explained later and therefore, a reflecting plate having a high reflectance can be produced.

When plural types of particulate titanium oxides are used as the component (B), the total amount of these titanium oxides is preferably in the above range based on the component (A).

Also, the above particulate titanium oxide may be surface-treated with the intention of improving the characteristics thereof such as dispersibility. Although no particular limitation is imposed on the surface treatment, surface treatment using an inorganic metal oxide is preferable from the viewpoint of improving the dispersibility and weatherability. Alumina (aluminum oxide) is preferable as the inorganic metal oxide. Also, particulate titanium oxide which has not been surface-treated is preferable from the viewpoint of heat resistance and strength as long as it is free from coagulation and easily handled. When particulate titanium oxide which has been surface treated (surface-treated particulate titanium oxide) is used as the component (B), the amount of the component (B) to be blended may be selected based on the total weight of the surface-treated particulate titanium oxide because the surface treatment amount of the surface-treated particulate titanium oxide is usually small.

Examples of the commercially available product of particulate titanium oxide as the component (B) include “TIPAQUE CR-60” and “TIPAQUECR-58” manufactured by Ishihara Sangyo Kaisha, Ltd.

### <Component (C)>

The component (C) is at least one compound selected from the group consisting of fatty acid amides and fatty acid metal salts. Plural types of compounds selected from the above group may be mixed and used as the component (C).

These fatty acid amides and fatty acid metal salts are well-known (see, for example, the publication of JP-A No. 2003-12908) as the auxiliaries (plasticization stabilizers) used to stabilize the time of plasticization when resin compositions containing a liquid-crystalline polyester are melted and molded. The facts that fatty acid amides and fatty acid metal salts have the effect of improving the reflectance and that a reflecting plate or the like which develops a high reflectance can be produced as a result of synergistic effects with the component (B) cannot be easily inferred from the conventional inventions which refer to the plasticization stabilizer, but are based on the original findings of the inventors of the present invention. As mentioned above, the inventors of the present invention have found that the component (C) develops the ability to improve the reflectance. In the liquid-crystalline polyester resin mixture of the present invention, the component (C) also has the advantage that it can, at the same time, develop the effect (measuring stabilization) which the component (C) itself has as the plasticization stabilizer.

As the above fatty acid amide, those represented by the following formula (1) are preferable.

R¹—CO—NH₂ (1)

wherein R¹ represents a saturated hydrocarbon group having 10 to 30 carbon atoms or an unsaturated hydrocarbon group having 10 to 30 carbon atoms. These saturated hydrocarbon group and the unsaturated hydrocarbon group may be linear or branched.

Specific and preferable examples of the fatty acid amide include decanoic acid amide, dodecylic acid amide, myristic acid amide, palmitic acid amide, stearic acid amide, linoleic acid amide, linolenic acid amide, oleic acid amide, elaidic acid amide, eicosanoic acid amide, behenic acid amide, erucic acid amide, cerotic acid amide and montanic acid amide.

The melting point of the fatty acid amide is preferably 30° C. or more and more preferably 50° C. or more. If a fatty acid amide having a melting point less than 30° C. is used as the component (C), a part of the fatty acid amide is vaporized when the liquid-crystalline polyester resin mixture is pre-dried before molding a reflecting plate or the like, and there is the case where only insufficient reflectance improving effects are obtained. Also, there is a tendency that the measuring stabilization effects in the molding processing are decreased. The fatty acid amide has a powdery form having an average particle diameter of, preferably, 100 μm or less and more preferably 50 μm or less to make it easy to mix with a pellet-form liquid-crystalline polyester resin composition which will be explained later. The average particle diameter is a volume average particle diameter found by measuring using the laser diffraction scattering method.

Next, the fatty acid metal salt will be described. As the fatty acid constituting the fatty acid metal salt, those having 10 or more carbon atoms are preferable and those having 10 or more and 30 or less carbon atoms are more preferable. Specific examples of the fatty acid include dodecylic acid, myristic acid, palmitic acid, stearic acid, eicosanoic acid, behenic acid, lignoceric acid and montanic acid.

The metal ion constituting the fatty acid metal salt is preferably the group 1, group 2 or group 12 metals in the periodic chart, more preferably group 2 alkaline earth metal ions and even more preferably a calcium ion.

Specific and preferable examples of the fatty acid metal salt include calcium myristate, sodium myristate, calcium stearate, sodium stearate, zinc stearate, calciummontanate and sodium montanate. Calcium stearate and calcium montanate are preferable from the viewpoint of availability.

Although a fatty acid amide, a fatty acid metal salt or combinations of these compounds may be used as the component (C) to be used in the present invention, it is particularly preferable to use a fatty acid amide as the component (C). When a fatty acid amide is used as the component (C), this has the advantage that when the liquid-crystalline polyester resin mixture of the present invention is used to carry out the melt-molding process, the metal mold to be used in the melt-molding process can be sufficiently prevented from being contaminated.

The amount of the component (C) to be blended is preferably 0.005 to 0.15 parts by weight and more preferably 0.01 to 0.1 parts by weight based on 100 parts by weight of the component (A).

### <Liquid-Crystalline Polyester Resin Mixture>

The liquid-crystalline polyester resin mixture of the present invention includes the aforementioned components (A), (B) and (C) and may further contain an inorganic filler (hereinafter referred to as an “inorganic filler”) other than particulate titanium oxide as the component (D) with the intention of, for example, improving mechanical characteristics.

In this case, the amount of the component (D) to be blended is preferably 60 parts by weight or less based on a total of 100 parts by weight of the components (A), (B) and (C). When the amount of the component (D) to be blended is in the above range, the desired effects of the component (D) can be adequately produced without significantly impairing the reflectance of the obtained reflecting plate. When the component (D) is used, the amount of the component (D) to be blended may be optionally optimized according to the type of the component (D) and the characteristics required for the component (D). In the case where, for example, an inorganic filler is used as the component (D) with the intention of obtaining a molded article having high mechanical strength, the amount of the inorganic filler to be blended is preferably 20 parts by weight or more based on a total of 100 parts by weight of the components (A), (B) and (C). When the amount of the component (D) to be blended is in this range, an improvement in characteristics such as mechanical strength can be attained while sufficiently limiting a reduction in the reflectance of the reflecting plate to be obtained and a reduction in color tone. Also, there is a tendency that a pellet-like liquid-crystalline polyester resin composition to be used in the production of a liquid-crystalline polyester resin mixture as will be explained later is granulated relatively easily.

Examples of the component (D) include white pigments other than titanium oxide, such as zinc oxide, zinc sulfide and lead white; inorganic fibers such as glass fibers, carbon fibers, metal fibers, alumina fibers, boron fibers, titanic acid fibers, wollastonite and asbestos; powders such as calcium carbonate, alumina, aluminum hydroxide, kaolin, talc, clay, mica, glass flake, glass beads, hollow glass beads, dolomite, various metal powders, barium sulfate, potassium titanate and calcined gypsum; and particulate, plate or whisker inorganic fillers of, for example, silicon carbide, alumina, boron nitride, aluminum borate or silicon nitride.

Among these fillers, inorganic fibers such as glass fibers and wollastonite and particulate, plate or whisker inorganic fillers of, for example, aluminum borate or silicon nitride and talc are preferable to impart practical mechanical strength to the obtained reflecting plate without significantly decreasing the reflectance of the reflecting plate.

Particularly, glass fibers are preferable from the viewpoint that practical mechanical strength can be imparted to the obtained reflecting plate without significantly decreasing the reflectance of the reflecting plate. The glass fibers are also useful from the viewpoint that they are easily available from the market at low costs.

Although there is the case where a collecting agent is used in such an inorganic filler, the amount of the collecting agent to be used is preferably smaller in view of limiting a reduction in color tone to keep the high reflectance of the reflecting plate.

The liquid-crystalline polyester resin mixture of the present invention may be blended with at least one type of usual additives such as fluorine resins, higher fatty acid ester compounds, releasability improvers, coloring materials such as dyes and pigments, antioxidants, thermal stabilizers, fluorescent whitening agents, ultraviolet absorbers, antistatic agents and surfactants to the extent that the object of the present invention is not impaired. Also, materials having external lubricating effects such as higher fatty acids, higher fatty acid esters and fluorocarbon type surfactants may be added.

The liquid-crystalline polyester resin mixture of the present invention can be obtained by mixing the components (A), (B) and (C) and the component (D) to be used as necessary by using a mixer such as a Henshel mixer or a tumbler and then by melt-kneading the mixture by using an extruder. However, it is preferable that after the components (A) and (B) and the component (D) to be used as necessary be mixed by using a mixer, the mixture be melt-kneaded by using an extruder to prepare a pellet-form liquid-crystalline polyester resin composition, which is then mixed with the component (C) to produce the liquid-crystalline polyester resin mixture of the present invention. When a liquid-crystalline polyester resin composition produced in advance is mixed with the component (C), the coloring caused by the component (C) which is relatively easily colored by heat treatment is prevented sufficiently, making it possible to produce a liquid-crystalline polyester resin mixture limited in coloring. Also, the production method in which the component (C) is mixed after the preparation of a liquid-crystalline polyester resin mixture has the advantage that the effect of the component (C) as the plasticization stabilizer can be produced more efficiently.

### <Reflecting Plate>

The liquid-crystalline polyester resin mixture thus obtained may be molded by various usual melt-molding means such as the injection molding method, the injection compression molding method and the extrusion molding method. Among these methods, the injection molding method is preferable. According to the injection molding method, molded articles having relatively complicated shapes are easily obtained.

Also, in the case of producing a reflecting plate by injection molding using the liquid-crystalline polyester resin mixture, a reflecting plate having a thin-wall part can be produced. The resin mixture is particularly useful to produce a reflecting plate having a part having a thickness of 0.03 to 3 mm. The thickness of the thin-wall part of the reflecting plate is preferably 0.05 to 2 mm and more preferably 0.05 to 1 mm taking the mechanical strength of the reflecting plate itself into consideration. The reflecting plate having such a thickness has a high reflectance because the synergetic effect of the components (B) and (C) is developed. Also, the stabilization of the plasticization time during melt-molding can be attained by the measuring stabilization effects of the component (C).

The molding temperature relating to the melt-molding such as injection molding is preferably higher by about 10 to 60° C. than the fluidization temperature of the liquid-crystalline polyester resin mixture to be used in the melt-molding. When the molding temperature is less than this temperature range, the fluidity of the resin mixture is extremely dropped, which tends to bring about impaired moldability and a reduction in the strength of the reflecting plate. When the molding temperature exceeds the above temperature range on the other hand, the liquid-crystalline polyester is significantly deteriorated and there is therefore a fear as to a reduction in the reflectance of the reflecting plate. The fluidization temperature of the liquid-crystalline polyester resin mixture may be measured by a capillary type rheometer in the same manner as in the method explained as the method of measuring the fluidization temperature of a liquid-crystalline polyester.

A reflecting plate having a reflectance of at least 70% in view of light with a wavelength of 460 nm can be obtained by using the liquid-crystalline polyester resin mixture of the present invention. The reflectance can be determined by, for example, Total Light Reflectance Measuring Method A, provided in JIS K7105-1981 using a standard white plate made of barium sulfate.

### <Light-Emitting Device>

As mentioned above, the liquid-crystalline polyester resin mixture of the present invention is particularly useful to produce a reflecting plate. The reflecting plate thus obtained can be preferably used as reflecting plates which need to reflect the light used in electric, electronic, automobile and mechanical fields, and particularly, light in the visible light region. The reflecting plate may be preferably used for lamp reflectors of light source devices such as a halogen lamp and HIDs, and also for reflecting plates of light-emitting devices and display devices using light-emitting elements such as LEDs or organic ELs. Particularly in light-emitting devices using LEDs as the light-emitting elements, the reflecting plate is sometimes exposed to a high-temperature circumstance such as those in an element packaging process and a soldering process during the course of the production process. However, the reflecting plate obtained by the present invention has the advantage that it produces no deformation such as blistering even if it undergoes such a high-temperature process. Therefore, when the reflecting plate obtained by the present invention is used in a light-emitting device using LEDs as the light-emitting element, a light-emitting device superior in characteristics such as luminance can be obtained.

The invention being thus described, it will be apparent that the same may be varied in many ways. Such variations are to be regarded as within the spirit and scope of the invention, and all such modifications as would be apparent to one skilled in the art are intended to be within the scope of the following claims.

### Examples

The present invention is described in more detail by following Examples, which should not be construed as a limitation upon the scope of the present invention.

In Examples and Comparative Examples, reflectance was measured by the following method. Reflectance:

In each of Examples and Comparative Examples, a test piece (reflecting plate) of 64 mm×64 mm×1 mm was prepared using the resin mixture which had been obtained therein, and the diffuse reflectance of the test piece was measured with respect to light having a wavelength of 460 nm using an automatic spectrophotometer (“U-3500,” manufactured by Hitachi, Ltd.). The reflectance is a relative value which is obtained under such a condition that the diffuse reflectance of a standard white plate made of barium sulfate is regarded as 100%.

The components (B), (C) and (D) which were used in Examples and Comparative Examples are as follows.

### <Component (B)>

### Titanium Oxide Filler 1:

TIPAQUE CR-60, manufactured by Ishihara Sangyo Kaisha, Ltd., (alumina surface-treated product; average particle diameter: 0.21 μm)

### Titanium Oxide Filler 2:

TIPAQUE CR-58, manufactured by Ishihara Sangyo Kaisha, Ltd., (alumina surface-treated product; average particle: diameter 0.28 μm)

### <Component (C)>

### Erucic Acid Amide:

Armoslip E, manufactured by Lion-Akzo Co., Ltd.

### Calcium Stearate:

Calcium stearate, manufactured by Wako Pure Chemical Industries, Ltd.

### Calcium Montanate:

Rikomonto CaV102, manufactured by Clariant (Japan) K. K.

### <Component (D)>

### Glass Fiber 1:

EFH75-01, manufactured by Central Glass Co., Ltd.

### Glass Fiber 2:

CS03JAPX-1, manufactured by Owens Corning Japan

### Glass Fiber 3:

EFDE50-01, manufactured by Central Glass Co., Ltd.

### Reference Example 1

### Preparation of Liquid-Crystalline Polyester 1 as a Component (A)

A reactor equipped with a stirrer, a torque meter, a nitrogen gas introducing tube, a temperature gage and a reflux condenser was charged with 994.5 g (7.2 mol) of parahydroxybenzoic acid, 446.9 g (2.4 mol) of 4,4′-dihydroxybiphenyl, 299.0 g (1.8 mol) of terephthalic acid, 99.7 g (0.6 mol) of isophthalic acid and 1347.6 g (13.2 mol) of acetic acid anhydride, to which 0.2 g of 1-methylimidazole was then added. After the atmosphere in the reactor was sufficiently replaced with a nitrogen gas, the mixture was heated to 150° C. in a nitrogen gas stream over 30 minutes and was refluxed for one hour while keeping this temperature.

Then, 0.9 g of 1-methylimidazole was added to the reaction mixture, which was then heated to 320° C. over 2 hours and 50 minutes while distilling fractional byproduct acetic acid and unreacted acetic acid anhydride off. The time at which a rise in torque was seen was defined as the end of the reaction. When the reaction was finished, the reaction mixture was cooled to ambient temperature to obtain a prepolymer.

After the obtained prepolymer was crushed by a coarse crusher, the powder obtained by the crushing was heated from ambient temperature to 250° C. over one hour, heated from 250° C. to 285° C. over 5 hours and then kept at 285° C. for 3 hours in a nitrogen atmosphere to undergo solid phase polymerization. The obtained polymer was cooled to obtain a liquid-crystalline polyester 1. The fluidization start temperature of the liquid-crystalline polyester 1 was 327° C.

### Reference Example 2

### Preparation of Liquid-Crystalline Polyester 2 as another Component (A)

A reactor equipped with a stirrer, a torque meter, a nitrogen gas introducing tube, a temperature gage and a reflux condenser was charged with 994.5 g (7.2 mol) of parahydroxybenzoic acid, 446.9 g (2.4 mol) of 4,4′-dihydroxybiphenyl, 358.8 g (2.16 mol) of terephthalic acid, 39.9 g (0.24 mol) of isophthalic acid and 1347.6 g (13.2 mol) of acetic acid anhydride, to which 0.2 g of 1-methylimidazole. was then added. After the atmosphere in the reactor was sufficiently replaced with a nitrogen gas, the mixture was heated to 150° C. in a nitrogen gas stream over 30 minutes and was refluxed for one hour while keeping this temperature. Then, the reaction mixture was then heated to 320° C. over 2 hours and 50 minutes while distilling fractional byproduct acetic acid and unreacted acetic acid anhydride off. The time at which a rise in torque was seen was defined as the end of the reaction. When the reaction was finished, the reaction mixture was cooled to ambient temperature to obtain a prepolymer. After the obtained prepolymer was crushed by a coarse crusher, the powder obtained by the crushing was heated from ambient temperature to 250° C. over one hour, heated from 250° C. to 305° C. over 5 hours and then kept at 305° C. for 3 hours in a nitrogen atmosphere to undergo solid phase polymerization. The obtained polymer was cooled to obtain a liquid-crystalline polyester 2. The fluidization start temperature of the liquid-crystalline polyester 2 was 357° C.

### Examples 1 to 9 and Comparative Examples 1 to 7

The components (B) and (D) shown in Table 1 were blended with each of 100 parts by weight of the component (A) shown in Table 1 in the amount shown in Table 1. The mixture was kneaded by a twin-screw extruder (“PCM-30,” manufactured by Ikegai Corporation) to prepare a pellet-like liquid-crystalline polyester resin composition. Then, the component (C) shown in Table 1 was added to and mixed with the obtained liquid-crystalline polyester resin composition in each ratio shown in Table 1. Each mixture was dried at 120° C. for 3 hours in an oven. The dried pellet was molded at 340° C. by an injection molding machine (“PS40E5ASE-model” manufactured by Nissei Plastic Industrial Co., Ltd. to obtain a test piece of a reflecting plate of 64 mm×64 mm×1 mm. Also, in the molding, each plasticization time in continuous 30 shots was measured to evaluate the stability (average and standard deviation of the plasticization times) of the test piece. Also, the same molding was carried out using a metal mold with a mirror-finished surface to obtain a test piece for measuring reflectance. The results of the measurements of the average and standard deviation of the plasticization times in the molding, and the results of the reflectance measured using the test piece for measuring reflectance are shown in Table 1.

TABLE 1

| | | Comparative | | Comparative | | Comparative | | | Comparative |
|---|---|---|---|---|---|---|---|---|---|
| | | Example 1 | Example 1 | Example 2 | Example 2 | Example 3 | Example 3 | Example 4 | Example 4 |
| Component | Liquid- | 100 | 100 | 100 | 100 | 100 | 100 | 100 | — |
| (A) | crystalline | | | | | | | | |
| | polyester 1 | | | | | | | | |
| | Liquid- | — | — | — | — | — | — | — | 100 |
| | crystalline | | | | | | | | |
| | polyester 2 | | | | | | | | |
| Component | Titanium | 80 | 80 | 40 | 40 | — | — | — | 40 |
| (B) | oxide filler 1 | | | | | | | | |
| | Titanium | — | — | — | — | 55 | 55 | 55 | — |
| | oxide filler 2 | | | | | | | | |
| Component | Glass fiber 1 | — | — | 60 | 60 | — | — | — | 60 |
| (D) | Glass fiber 2 | 20 | 20 | — | — | 27 | 27 | 27 | — |
| | Glass fiber 3 | — | — | — | — | — | — | — | — |
| Component | Erucic acid | — | 0.06 | — | 0.03 | — | 0.02 | — | — |
| (C) | amide | | | | | | | | |
| | Calcium | — | — | — | — | — | — | — | — |
| | stearate | | | | | | | | |
| | Calcium | — | — | — | — | — | — | 0.03 | — |
| | montanate | | | | | | | | |
| Reflectance (%) with | | 81.9 | 82.5 | 79.2 | 80.3 | 86.9 | 87.4 | 87.5 | 69.1 |
| respect to light having | | | | | | | | | |
| a wavelength of 460 nm | | | | | | | | | |
| Plasticization | Average time | 13 | 10 | 16 | 9 | 20 | 11 | 8 | 13 |
| | Standard | 2.0 | 0.6 | 10.5 | 0.5 | 18.2 | 0.6 | 0.3 | 1.6 |
| | deviation | | | | | | | | |

| | | | Comparative | Comparative | | | Comparative | | |
|---|---|---|---|---|---|---|---|---|---|
| | | Example 5 | Example 5 | Example 6 | Example 6 | Example 7 | Example 7 | Example 8 | Example 9 |
| Component | Liquid- | — | — | — | — | — | — | — | — |
| (A) | crystalline | | | | | | | | |
| | polyester 1 | | | | | | | | |
| | Liquid- | 100 | 100 | 100 | 100 | 100 | 100 | 100 | 100 |
| | crystalline | | | | | | | | |
| | polyester 2 | | | | | | | | |
| Component | Titanium | 40 | 40 | 40 | 40 | 40 | — | — | — |
| (B) | oxide filler 1 | | | | | | | | |
| | Titanium | — | — | — | — | — | 55 | 55 | 55 |
| | oxide filler 2 | | | | | | | | |
| Component | Glass fiber 1 | 60 | 60 | 60 | 60 | 60 | — | — | — |
| (D) | Glass fiber 2 | — | — | — | — | — | — | — | — |
| | Glass fiber 3 | — | — | — | — | — | 27 | 27 | 27 |
| Component | Erucic acid | 0.03 | 0.002 | 0.2 | — | — | — | 0.02 | — |
| (C) | amide | | | | | | | | |
| | Calcium | — | — | — | 0.06 | — | — | — | — |
| | stearate | | | | | | | | |
| | Calcium | — | — | — | — | 0.06 | — | — | 0.03 |
| | montanate | | | | | | | | |
| Reflectance (%) with | | 70.1 | 68.7 | 68.2 | 70.6 | 70.6 | 80.0 | 81.1 | 80.9 |
| respect to light having | | | | | | | | | |
| a wavelength of 460 nm | | | | | | | | | |
| Plasticization | Average time | 8 | 13 | 15 | 11 | 11 | 13 | 8 | 7 |
| | Standard | 0.2 | 2.9 | 1.0 | 0.8 | 0.3 | 6.1 | 0.2 | 0.2 |
| | deviation | | | | | | | | |

As shown in Table 1, the test piece of the reflecting plate obtained from the liquid-crystalline polyester resin mixture of each example had a higher effect on the improvement of reflectance than the test piece of the reflecting plate obtained from the liquid-crystalline polyester resin mixture of each comparative example in which the component (C) was not blended. Also, the measuring stabilization effects of the component (C) were well developed so that the plasticization time was shortened and stable plasticization was attained.

What is claimed is:

1. A liquid-crystalline polyester resin mixture comprising the following components (A), (B) and (C):
(A) a liquid-crystalline polyester;
(B) particulate titanium oxide; and
(C) at least one compound selected from the group consisting of a fatty acid amide and a fatty acid metal salt,
wherein the resin mixture contains the component (B) in an amount of 40 to 80 parts by weight and the component (C) in an amount of 0.005 to 0.15 parts by weight, both the amounts being based on 100 parts by weight of the component (A) in the resin mixture.

2. The resin mixture according to claim 1, the resin mixture being obtainable by a method comprising the steps of melt-kneading the components (A) and (B) to obtain a liquid-crystalline polyester resin composition in a pellet form, and mixing the composition with the component (C).

3. The resin mixture according to claim 1, wherein the component (C) is a fatty acid amide represented by the following formula (1):
R¹—CO—NH₂ (1)
wherein R¹ represents a saturated hydrocarbon group having 10 to 30 carbon atoms or an unsaturated hydrocarbon group having 10 to 30 carbon atoms.

4. The resin mixture according to claim 1, further comprising the following component (D):
(D) an inorganic filler other than particulate titanium oxide.

5. The resin mixture according to claim 4, wherein the resin mixture contains the component (D) in an amount of 60 parts by weight or smaller based on 100 parts by weight of the total amount of the components (A), (B) and (C) in the resin mixture.

6. The resin mixture according to claim 4, wherein the component (D) is a glass fiber.

7. A molded article obtainable by molding the resin mixture according to claim 1.

8. A reflecting plate obtainable by molding the resin mixture according to claim 1.

9. The reflecting plate according to claim 8, which has a part with a thickness of 0.03 mm to 3 mm.

10. The reflecting plate according to claim 8, wherein the reflecting plate has a reflectance of at least 70% with respect to light having a wavelength of 460 nm.

11. A light-emitting device comprising the reflecting plate according to claim 8 and a light-emitting element.

12. The light-emitting device according to claim 11, wherein the light-emitting element is a light-emitting diode.
